(19) United States
(12) Patent Application Publication
(10) Pub. No.: US 2017/0309623 A1
(43) Pub. Date: Oct. 26, 2017

(54) METHOD, APPARATUS, AND SYSTEM FOR INCREASING DRIVE CURRENT OF FINFET DEVICE

(71) Applicant: GLOBALFOUNDRIES INC., Grand Cayman (KY)

(72) Inventors: Shesh Mani Pandey, Saratoga Springs, NY (US); Baofu Zhu, Clifton Park, NY (US)

(73) Assignee: GLOBALFOUNDRIES INC., Grand Cayman (KY)

(21) Appl. No.: 15/135,358

(22) Filed: Apr. 21, 2016

(51) Int. Cl. H01L 27/088; H01L 29/10; H01L 21/8234; H01L 29/78; H01L 21/67

(52) U.S. Cl. CPC H01L 27/0886; H01L 29/7853; H01L 21/67155; H01L 21/823431; H01L 29/1037

(57) ABSTRACT

We disclose semiconductor devices, comprising a semiconductor substrate comprising bulk silicon; and a plurality of fins formed on the semiconductor substrate; wherein each of the plurality of fins comprises a lower portion disposed on the semiconductor substrate and having a first width, and an upper portion disposed on the lower portion and having a second width, wherein the second width is greater than the first width, as well as methods, apparatus, and systems for fabricating such semiconductor devices.

### BACKGROUND OF THE INVENTION

### Field of the Invention

Generally, the present disclosure relates to the manufacture and use of sophisticated semiconductor devices, and, more specifically, to various methods, structures, and systems for increasing the drive current of FinFET devices.

### Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

A typical integrated circuit (IC) chip includes a stack of several levels or sequentially formed layers of shapes. Each layer is stacked or overlaid on a prior layer and patterned to form the shapes that define devices (e.g., fin field effect transistors (FinFETs)) and connect the devices into circuits. In a typical state of the art complementary insulated gate FinFET process, a fin (rectangular in cross-section) is formed on a surface of the wafer, and a gate is formed over the fin.

One challenge facing FinFETs is that the drive current may be undesirably low for various intended uses. One attempt to solve this challenge has been to increase the top and bottom critical dimensions of a rectangular or straight fin in order to increase the area. However, doing so significantly increases the leakage current of the FinFET with a negligible increase on drive current.

Therefore, it would be desirable to have FinFETs with increased drive current, and especially without a corresponding significant increase in leakage current.

The present disclosure may address and/or at least reduce one or more of the problems identified above regarding the prior art and/or provide one or more of the desirable features listed above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to semiconductor devices, comprising a semiconductor substrate comprising bulk silicon; and a plurality of fins formed on the semiconductor substrate; wherein each of the plurality of fins comprises a lower portion disposed on the semiconductor substrate and having a first width, and an upper portion disposed on the lower portion and having a second width, wherein the second width is greater than the first width, as well as methods, apparatus, and systems for fabricating such semiconductor devices.

Semiconductor devices in accordance with embodiments of the present disclosure may have an increased drive current, e.g., a drive current at least about 10% greater than a drive current of a comparable semiconductor device comprising a plurality of comparable fins, wherein each of the comparable fins has a lower portion having the first width and an upper portion having the first width. Semiconductor devices in accordance with embodiments of the present disclosure may have an increased drive current without a significant increase in leakage current, e.g., a leakage current no more than about 20% greater than a leakage current of the comparable semiconductor device.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a first semiconductor device in accordance with embodiments herein;

FIG. 2 illustrates a stylized depiction of the first semiconductor device, further comprising a gate, in accordance with embodiments herein;

FIG. 3 illustrates a final dielectric material and metal gate profile for a T-shaped fin in accordance with embodiments herein, and a straight fin as known in the art;

FIG. 4A presents the relationship between Ieff and Isoff for a T-shaped fin in accordance with embodiments herein and for a straight fin as known in the art;

FIG. 4B presents the relationship between Vtsat and Isoff for a T-shaped fin in accordance with embodiments herein and for a straight fin as known in the art;

FIG. 4C presents the relationship between Itsat and Ieff for a T-shaped fin in accordance with embodiments herein and for a straight fin as known in the art;

FIG. 5A illustrates the first semiconductor device in accordance with embodiments herein after a first processing step;

FIG. 5B illustrates the first semiconductor device in accordance with embodiments herein after a second processing step;

FIG. 5C illustrates the first semiconductor device in accordance with embodiments herein after a third processing step;

FIG. 5D illustrates the first semiconductor device in accordance with embodiments herein after a fourth processing step;

FIG. 5E illustrates the first semiconductor device in accordance with embodiments herein after a fifth processing step;

FIG. 5F illustrates the first semiconductor device in accordance with embodiments herein after a sixth processing step;

FIG. 5G illustrates the first semiconductor device in accordance with embodiments herein after a seventh processing step;

FIG. 5H illustrates the first semiconductor device in accordance with embodiments herein after a eighth processing step;

FIG. 5I illustrates the first semiconductor device in accordance with embodiments herein after a ninth processing step;

FIG. 5J illustrates the first semiconductor device in accordance with embodiments herein after a tenth processing step;

FIG. 5K illustrates the first semiconductor device in accordance with embodiments herein after an eleventh processing step;

FIG. 5L illustrates the first semiconductor device in accordance with embodiments herein after a twelfth processing step;

FIG. 6 illustrates a semiconductor device manufacturing system for manufacturing a device in accordance with embodiments herein; and

FIG. 7 illustrates a flowchart of a method in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for FinFET semiconductor devices which may have increased drive current without a corresponding significant increase in leakage current. For example, embodiments herein provide for a T-shaped fin for a FinFET device, wherein the T-shaped fin may provide for increased drive current without a corresponding significant increase in leakage current.

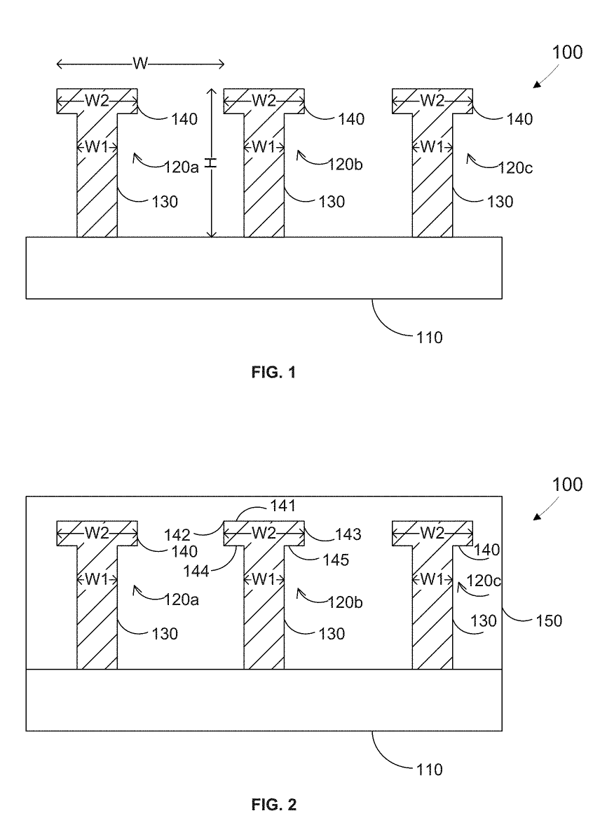

Turning to FIG. 1, in one embodiment, the present disclosure relates to a semiconductor device 100. The semiconductor device 100 may comprise a semiconductor substrate 110 and a plurality of fins 120a, 120b, 120c formed on the semiconductor substrate 110.

Any substrate material may be used in the semiconductor substrate 110. In one embodiment, the semiconductor substrate 110 comprises bulk silicon.

In the plurality of fins 120a, 120b, 120c, each fin 120 comprises a lower portion 130 disposed on the semiconductor substrate 110 and having a first width W1, and an upper portion 140 disposed on the lower portion 130 and having a second width W2, wherein the second width is greater than the first width (i.e., W2>W1). Such a fin 120 may be referred to herein as a “T-shaped fin.”

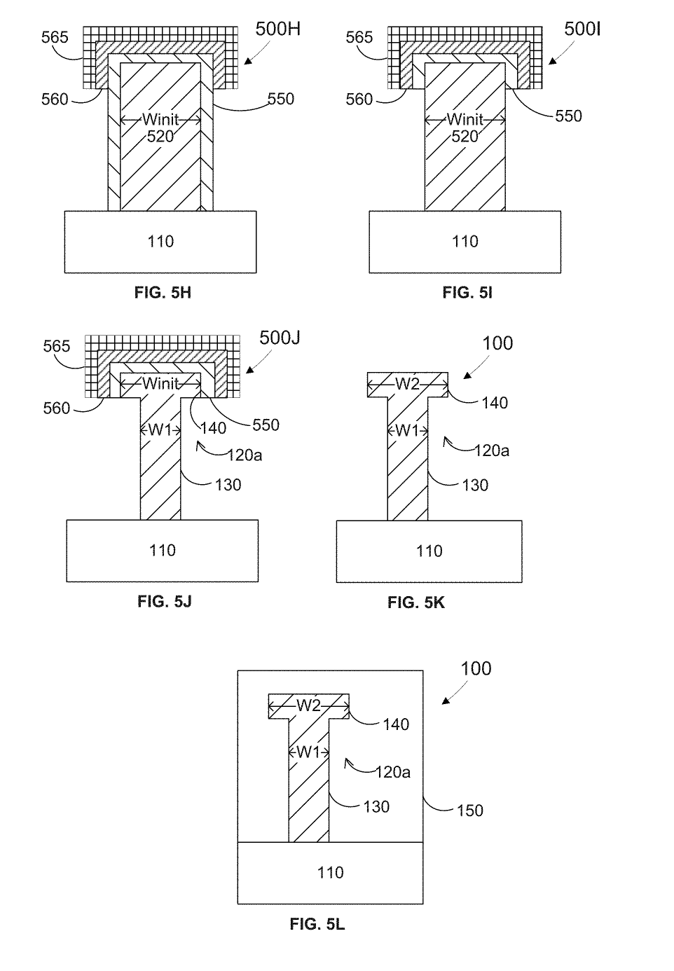

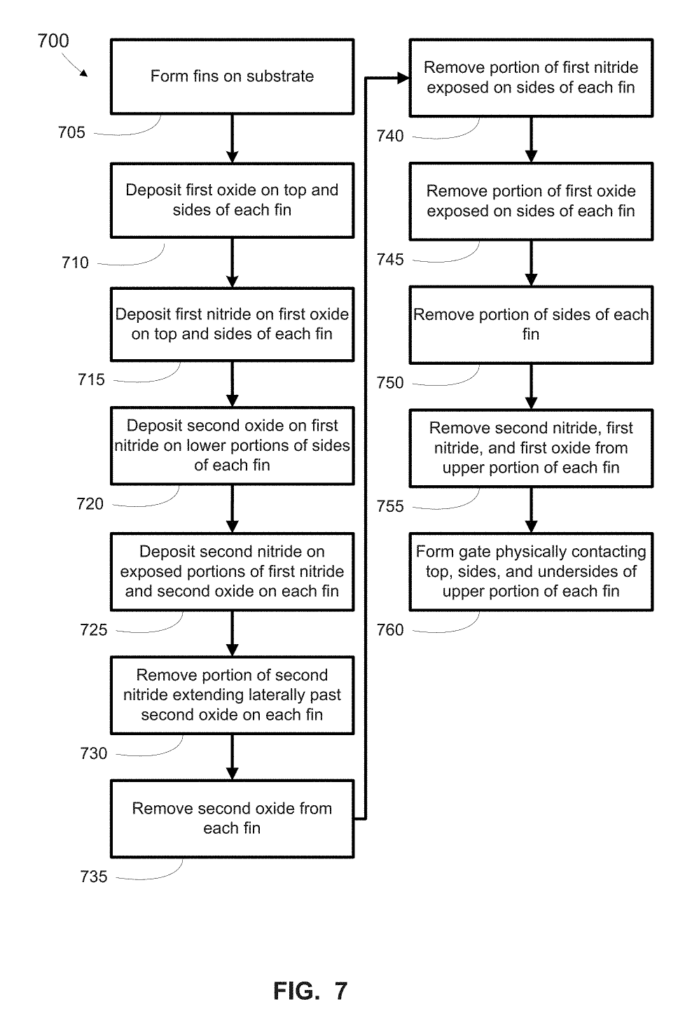

Each fin 120 may be formed of any appropriate material(s) known for use in FinFETs. Each fin 120 may comprise one material or a plurality of materials, such as interleaved layers of various materials (e.g., interleaved layers of silicon and silicon-germanium; interleaved layers of silicon-germanium with a first germanium concentration and silicon-germanium with a second germanium concentration, etc.) In one embodiment, the plurality of fins 120a, 120b, 120c may be formed by depositing one or more materials on the semiconductor substrate 110, with subsequent processing of the deposited materials, such as by embodiments to be described below with reference to FIGS. 5A-5K and FIG. 7. In one embodiment, the plurality of fins 120a, 120b, 120c may be formed from the same material as the semiconductor substrate 110, by removing portions of the substrate material between fins 520 (depicted in FIG. 5A-5G), with subsequent processing of the deposited materials, such as by embodiments to be described below.

Although FIG. 1 depicts three fins 120a, 120b, 120c, any plural number (i.e., two or more) fins 120 may be included in the semiconductor device 100.

In one embodiment, the first width W1 may be about 14 nm and the second width W2 may be from about 20 nm to about 40 nm. Alternatively or in addition, the plurality of fins 120a, 120b, 120c may have a pitch (distance W between corresponding structural features of adjacent fins, e.g., fins 120a, 120b) from about 22 nm to about 48 nm. Independently of the values of W1, W2, and W, each fin 120 may have a height H of about 41 nm.

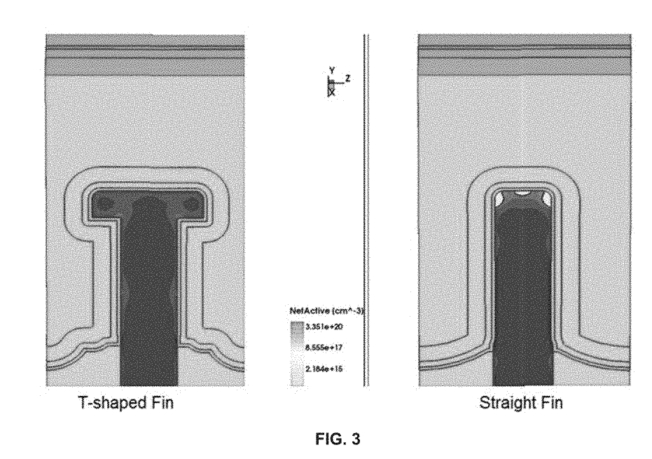

Turning to FIG. 2, the semiconductor device 100 may further comprise a gate 150 disposed on each fin 120 of the plurality of fins 120a, 120b, 120c, wherein the gate 150 physically contacts at least a top 141, a left side 142, a right side 143, a left underside 144, and a right underside 145 of at least the upper portion 140. (As depicted in FIG. 2, the gate 150 also physically contacts the left and right sides of the lower portion 130.

The gate 150 may comprise a plurality of layers, as is known in the art. For example, the gate 150 may comprise (from closest to each fin 120 to furthest from each fin 120) an interlayer dielectric, a high-K layer, and a polysilicon layer (not shown). The gate 150 may comprise alternative and/or additional layers known to the person of ordinary skill in the art.

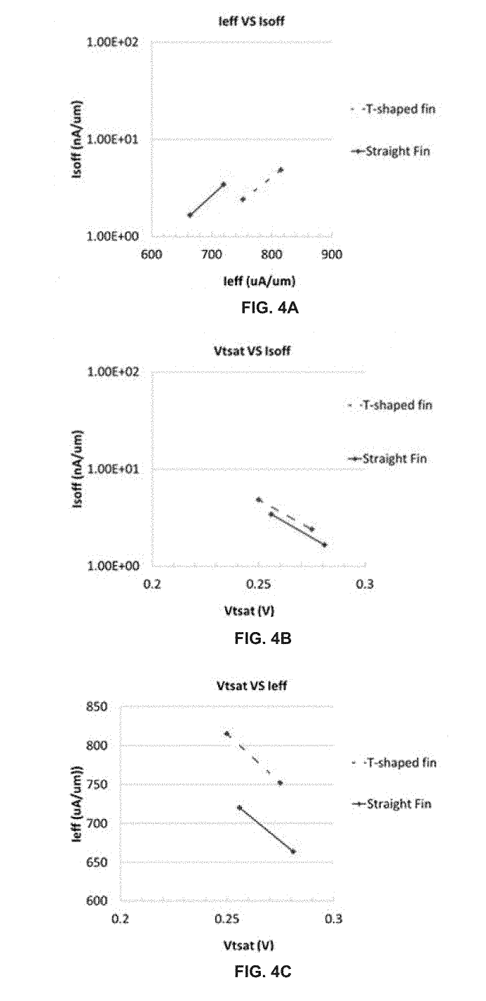

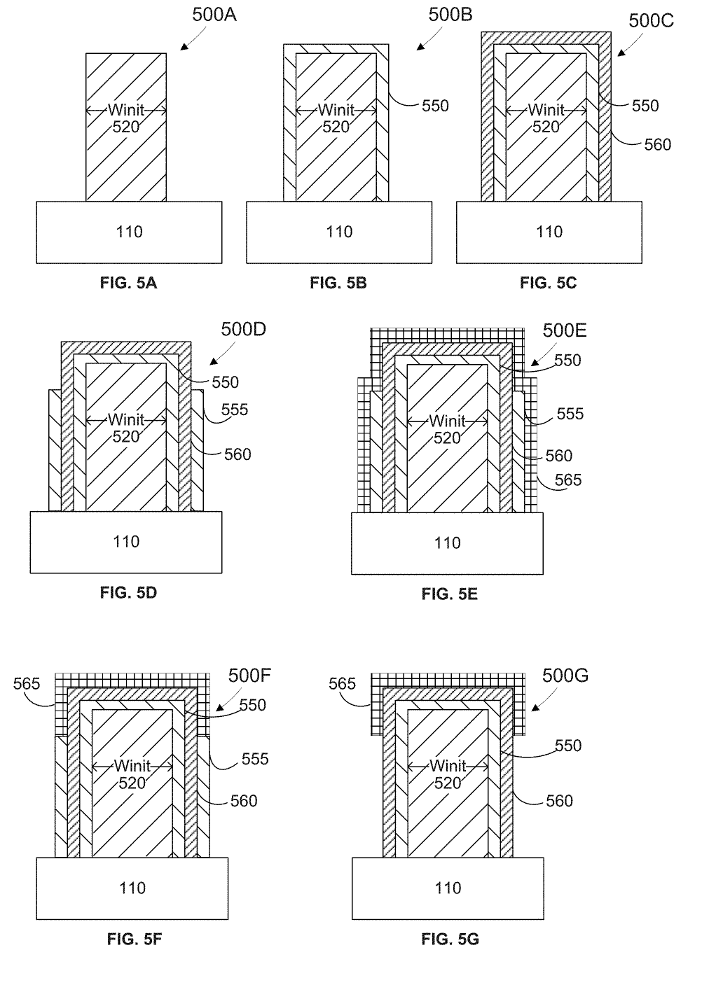

The semiconductor device 100 of FIG. 2, may have a drive current at least about 10% greater than a drive current of a comparable semiconductor device comprising a plurality of comparable fins, wherein each of the comparable fins has a lower portion having the first width and an upper portion having the first width (i.e., comparable fins having a rectangular cross-section, also termed a “straight fin” in FIGS. 3-4C). The semiconductor device 100 of FIG. 2 may have a leakage current no more than about 20% greater than a leakage current of the comparable semiconductor device.

Though not to be bound by theory, FIGS. 3-4C present data relating to the improved drive current and not significantly increased leakage current of the semiconductor device 100 comprising a T-shaped fin 120 compared to a straight fin as known in the art.

FIG. 3 presents fins surrounded by dielectric material and a metal gate for a straight fin as known in the art and a T-shaped fin according to embodiments of the present disclosure. As the example demonstrates, the T-shaped fin design depicted in FIG. 3 allows for a higher drive current drive while at the same time providing the benefit of a lack of significant increase in current leakage. This is not possible with the state of the art straight fin, the current path of which is limited by the surface area.

FIG. 4A presents the relationship between Ieff and Isoff for a T-shaped fin 120 in accordance with embodiments herein and for a straight fin as known in the art. As can be seen, at any given Isoff, the fin 120 has an Ieff (drive current) at least about 10% greater than the straight fin.

FIG. 4B presents the relationship between Vtsat and Isoff for a T-shaped fin 120 in accordance with embodiments herein and for a straight fin as known in the art. As can be seen, at any given Vtsat, the fin 120 has an Isoff (leakage current) no more than about 20% greater than the straight fin.

FIG. 4C presents the relationship between Vtsat and Ieff for a T-shaped fin 120 in accordance with embodiments herein and for a straight fin as known in the art. Similarly to FIG. 4A, at any given Vtsat, the fin 120 has an Ieff (drive current) at least about 10% greater than the straight fin.

In summary, FIGS. 3-4C show that the semiconductor device 100 comprising a T-shaped fin 120 may have an improved drive current and a not significantly increased leakage current compared to a comparable semiconductor device comprising a straight fin as known in the art.

The semiconductor device 100 of FIGS. 1-2 may be formed by forming a plurality of fins on a semiconductor substrate, wherein each fin of the plurality of fins has an initial width; and reducing a width of a lower portion of each fin to a first width, to yield a plurality of fins wherein each fin comprises an upper portion having disposed on the lower portion and having a second width, wherein the second width is greater than the first width.

In one embodiment, the semiconductor device 100 of FIGS. 1-2 may be formed by way of the intermediates depicted in FIGS. 5A-5K. Beginning with FIG. 5A, a fin 520 of a plurality of fins (additional fins not shown for the sake of brevity) is formed on the semiconductor substrate 110. The fin 520 has an initial width Winit.

FIG. 5B depicts an intermediate semiconductor device 500B after deposition of a first oxide 550 on at least a top, a left side, and a right side of each fin 520 of the plurality of fins. Any material known for use in oxide layers of FinFET devices may be used as the first oxide 550. In one embodiment, the first oxide 550 may comprise silicon oxide.

FIG. 5C depicts an intermediate semiconductor device 500C after deposition of a first nitride 560 on the first oxide 550 on at least the top, the left side, and the right side of each fin of the plurality of fins. Any material known for use in nitride layers of FinFET devices may be used as the first nitride 560. In one embodiment, the first nitride 560 may comprise silicon nitride.

FIG. 5D depicts an intermediate semiconductor device 500D after deposition of a second oxide 555 on the first nitride 560 on a lower portion of both the left side and the right side of each fin 520 of the plurality of fins. The lower portion on which the second oxide 555 is deposited corresponds to the lower portion 130 of the fin 120 of the final semiconductor device 100. Any material known for use in oxide layers of FinFET devices may be used as the second oxide 555. The second oxide 555 may comprise the same material as the first oxide 550, but need not. In one embodiment, the second oxide 555 may comprise silicon oxide.

FIG. 5E depicts an intermediate semiconductor device 500E after deposition of a second nitride 565 on a portion of the first nitride 560 and a portion of the second oxide 555 exposed on each fin 520 of the plurality of fins. In other words, the second nitride 565 may completely cover the top and sides of each fin 520. Any material known for use in nitride layers of FinFET devices may be used as the second nitride 565. The second nitride 565 may comprise the same material as the first nitride 565, but need not. In one embodiment, the second nitride 565 may comprise silicon nitride.

FIG. 5F depicts an intermediate semiconductor device 500F after removal of a portion of the second nitride 565 extending laterally beyond the second oxide 555 on both the left side and the right side of each fin 520 of the plurality of fins. In other words, the portion of the second nitride 565 disposed on the lower portion of the fin 520 is removed. Removal of the second nitride 565 may be effected using any technique known to the person of ordinary skill in the art having the benefit of the present disclosure.

FIG. 5G depicts an intermediate semiconductor device 500G after removal of the second oxide 555 from each fin 520 of the plurality of fins. Removal of the second oxide 555 may be effected using any technique known to the person of ordinary skill in the art having the benefit of the present disclosure.

FIG. 5H depicts an intermediate semiconductor device 500H after removal of a portion of the first nitride 560 exposed on the left side and the right side of each fin 520 of the plurality of fins. In other words, the portion of the first nitride 560 disposed on the lower portion of the fin 520 is removed. Removal of the first nitride 560 may be effected using any technique known to the person of ordinary skill in the art having the benefit of the present disclosure.

FIG. 5I depicts an intermediate semiconductor device 5001 after removal of a portion of the first oxide 550 exposed on the left side and the right side of each fin 520 of the plurality of fins. In other words, the portion of the first oxide 550 disposed on the lower portion of the fin 520 is removed. Removal of the first oxide 550 may be effected using any technique known to the person of ordinary skill in the art having the benefit of the present disclosure.

FIG. 5J depicts an intermediate semiconductor device 500J after removal of a portion of the fin 520 exposed on the left side and the right side of each fin 520 of the plurality of fins, to yield a plurality of fins wherein each fin (e.g., fin 120a) comprises a lower portion 130 disposed on the semiconductor substrate 110 and having a first width W1 less than the initial width Winit. Removal of the portion of the fin 520 may be effected using any technique known to the person of ordinary skill in the art having the benefit of the present disclosure.

FIG. 5K depicts the semiconductor device 100 after removal of the second nitride 565, first nitride 560, and first oxide 550 from an upper portion 140 of each fin (e.g., fin 120a) of the plurality of fins, to yield a semiconductor device 100 comprising the semiconductor substrate 110 and a plurality of fins wherein each fin (e.g., fin 120a) comprises an upper portion 140 disposed on the lower portion 130 and having a second width W2, wherein the second width is greater than the first width. In one embodiment, the second width W2 is equal to the initial width Winit. The various nitrides and oxide may be removed using any technique known to the person of ordinary skill in the art having the benefit of the present disclosure.

FIG. 5L depicts the semiconductor device 100 after formation of a gate 150 over each fin (e.g., fin 120a) of the plurality of fins. Formation of a gate over a fin can be performed as a routine matter by the person of ordinary skill in the art having the benefit of the present disclosure.

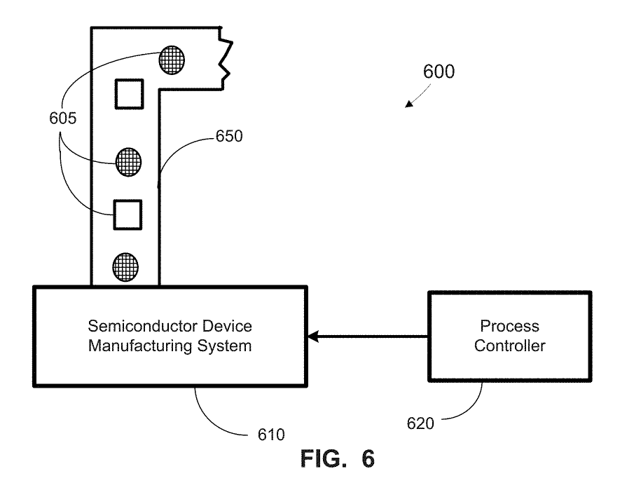

Turning now to FIG. 6, a stylized depiction of a system for fabricating a semiconductor device 100, in accordance with embodiments herein, is illustrated. The system 600 of FIG. 6 may comprise a semiconductor device manufacturing system 610 and a process controller 620. The semiconductor device manufacturing system 610 may manufacture semiconductor devices 100 based upon one or more instruction sets provided by the process controller 620. In one embodiment, the instruction set may comprise instructions to form a plurality of fins on a semiconductor substrate, wherein each fin of the plurality of fins has an initial width; and reduce a width of a lower portion of each fin to a first width, to yield a plurality of fins wherein each fin comprises an upper portion having disposed on the lower portion and having a second width, wherein the second width is greater than the first width.

In one embodiment, to reduce the width of each fin, the instruction set may comprise instructions to form a plurality of fins on a semiconductor substrate, wherein each fin of the plurality of fins has an initial width; deposit a first oxide on at least a top, a left side, and a right side of each fin of the plurality of fins; deposit a first nitride on the first oxide on at least the top, the left side, and the right side of each fin of the plurality of fins; deposit a second oxide on the first nitride on a lower portion of both the left side and the right side of each fin of the plurality of fins; deposit a second nitride on a portion of the first nitride and a portion of the second oxide exposed on each fin of the plurality of fins; remove a portion of the second nitride extending laterally beyond the second oxide on both the left side and the right side of each fin of the plurality of fins; remove the second oxide; remove a portion of the first nitride exposed on the left side and the right side of each fin of the plurality of fins; remove a portion of the first oxide exposed on the left side and the right side of each fin of the plurality of fins; remove a portion of the fin exposed on the left side and the right side of each fin of the plurality of fins, to yield a plurality of fins wherein each fin comprises a lower portion disposed on the semiconductor substrate and having a first width less than the initial width; and remove the second nitride, first nitride, and first oxide from an upper portion of each fin of the plurality of fins, to yield a semiconductor device comprising the semiconductor substrate and a plurality of fins wherein each fin comprises an upper portion disposed on the lower portion and having a second width, wherein the second width is greater than the first width.

In one embodiment, the instructions to form the plurality of fins on a semiconductor substrate may comprise instructions to form the plurality of fins with a pitch from about 22 nm to about 48 nm. Alternatively or in addition, the instruction set may further comprise instructions to form each fin with a height of about 41 nm.

In one embodiment, the instruction set may further comprise instructions to form a gate on each fin of the plurality of fins, wherein the gate physically contacts at least a top, a left side, a right side, a left underside, and a right underside of at least the upper portion.

In one embodiment, the first width may be about 14 nm and the second width may be from about 20 nm to about 40 nm. In one embodiment, the second width may be substantially equal to the initial width.

The semiconductor device manufacturing system 610 may be used to manufacture a semiconductor device 100 having a drive current at least about 10% greater than a drive current of a comparable semiconductor device comprising a plurality of comparable fins, wherein each of the comparable fins has a lower portion having the first width and an upper portion having the first width, and/or having a leakage current no more than about 20% greater than a leakage current of the comparable semiconductor device.

The semiconductor device manufacturing system 610 may comprise various processing stations, such as etch process stations, photolithography process stations, CMP process stations, etc. One or more of the processing steps performed by the semiconductor device manufacturing system 610 may be controlled by the process controller 620. The process controller 620 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 610 may produce semiconductor devices 605 (e.g., integrated circuits) on a medium, such as silicon wafers. The semiconductor device manufacturing system 610 may provide processed semiconductor devices 605 on a transport mechanism 650, such as a conveyor system. In some embodiments, the conveyor system may be sophisticated clean room transport systems that are capable of transporting semiconductor wafers. In one embodiment, the semiconductor device manufacturing system 610 may comprise a plurality of processing steps, e.g., the 1^{st} process step, the 2^{nd} process step, etc.

In some embodiments, the items labeled “605” may represent individual wafers, and in other embodiments, the items 605 may represent a group of semiconductor wafers, e.g., a “lot” of semiconductor wafers.

The system 600 may be capable of manufacturing various products involving various FinFET technologies, e.g., the system 600 may produce devices of CMOS technology, Flash technology, BiCMOS technology, power devices, memory devices (e.g., DRAM devices), NAND memory devices, and/or various other semiconductor technologies.

Generally, a method of forming a FinFET device in accordance with embodiments herein may comprise forming a plurality of fins on a semiconductor substrate, wherein each fin of the plurality of fins has an initial width; and reducing a width of a lower portion of each fin to a first width, to yield a plurality of fins wherein each fin comprises an upper portion having disposed on the lower portion and having a second width, wherein the second width is greater than the first width.

Turning to FIG. 7, a flowchart of a method 700 in accordance with embodiments herein is depicted. The method 700 may comprise forming (at 705) a plurality of fins on a semiconductor substrate, wherein each fin of the plurality of fins has an initial width. In one embodiment, the forming (at 705) of the plurality of fins on a semiconductor substrate may comprise forming the plurality of fins with a pitch from about 22 nm to about 48 nm. Alternatively or in addition, each fin may have a height of about 41 nm.

Thereafter, the method 700 may involve forming a structure to allow protection of an upper portion of each fin during subsequent processing steps to be performed on a lower portion of each fin. For example, the method 700 may comprise one or more of depositing (at 710) a first oxide on at least a top, a left side, and a right side of each fin of the plurality of fins; depositing (at 715) a first nitride on the first oxide on at least the top, the left side, and the right side of each fin of the plurality of fins; depositing (at 720) a second oxide on the first nitride on a lower portion of both the left side and the right side of each fin of the plurality of fins; and depositing (at 725) a second nitride on a portion of the first nitride and a portion of the second oxide exposed on each fin of the plurality of fins.

The method 700 may involve reducing the width of the lower portion of each fin of the plurality of fins. For example, the method 700 may comprise one or more of removing (at 730) a portion of the second nitride extending laterally beyond the second oxide on both the left side and the right side of each fin of the plurality of fins; removing (at 735) the second oxide from each fin of the plurality of fins; removing (at 740) a portion of the first nitride exposed on the left side and the right side of each fin of the plurality of fins; removing (at 745) a portion of the first oxide exposed on the left side and the right side of each fin of the plurality of fins; and removing (at 750) a portion of the fin exposed on the left side and the right side of each fin of the plurality of fins, to yield a plurality of fins wherein each fin comprises a lower portion disposed on the semiconductor substrate and having a first width less than the initial width.

The method 700 may also involve removing any protecting structures from the upper portion of each fin. For example, the method 700 may comprise removing (at 755) the second nitride, first nitride, and first oxide from an upper portion of each fin of the plurality of fins, to yield a semiconductor device comprising the semiconductor substrate and a plurality of fins wherein each fin comprises an upper portion disposed on the lower portion and having a second width, wherein the second width is greater than the first width.

In one embodiment, the first width is about 14 nm and the second width is from about 20 nm to about 40 nm. Alternatively or in addition, the second width may be substantially equal to the initial width.

The method 700 may further comprise forming (at 760) a gate on each fin of the plurality of fins, wherein the gate physically contacts at least a top, a left side, a right side, a left underside, and a right underside of at least the upper portion.

The method 700 may produce a semiconductor device, wherein the semiconductor device has a drive current at least about 10% greater than a drive current of a comparable semiconductor device comprising a plurality of comparable fins, wherein each of the comparable fins has a lower portion having the first width and an upper portion having the first width, and the semiconductor device has a leakage current no more than about 20% greater than a leakage current of the comparable semiconductor device.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

Those skilled in the art having the benefit of the present disclosure would appreciate that other geometric shapes developed at the top portion of a fin in a similar manner described herein, may also provide the benefit of increased current drive without significant increase in current leakage. Therefore, a fin that has a lower portion disposed on the semiconductor substrate and having a first width, and an upper portion disposed on the lower portion and having a second width, wherein the second width is greater than the first width, may provide the benefit of increased drive current without significant increase in current leakage.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. A semiconductor device, comprising:
a semiconductor substrate comprising bulk silicon; and
a plurality of fins formed on the semiconductor substrate;
wherein each of the plurality of fins comprises a lower portion disposed on the semiconductor substrate and having a first width, and an upper portion disposed on the lower portion and having a second width, wherein the second width is greater than the first width.

2. The semiconductor device of claim 1, wherein the first width is about 14 nm and the second width is from about 20 nm to about 40 nm.

4. The semiconductor device of claim 1, wherein the plurality of fins have a pitch from about 22 nm to about 48 nm.

5. The semiconductor device of claim 1, wherein each fin has a height of about 41 nm.

3. The semiconductor device of claim 1, further comprising a gate disposed on each fin of the plurality of fins, wherein the gate physically contacts at least a top, a left side, a right side, a left underside, and a right underside of at least the upper portion.

6. The semiconductor device of claim 3, wherein the semiconductor device has a drive current at least about 10% greater than a drive current of a comparable semiconductor device comprising a plurality of comparable fins, wherein each of the comparable fins has a lower portion having the first width and an upper portion having the first width, and the semiconductor device has a leakage current no more than about 20% greater than a leakage current of the comparable semiconductor device.

7. A method, comprising:
forming a plurality of fins on a semiconductor substrate, wherein each fin of the plurality of fins has an initial width; and
reducing a width of a lower portion of each fin to a first width, to yield a plurality of fins wherein each fin comprises an upper portion having disposed on the lower portion and having a second width, wherein the second width is greater than the first width.

8. The method of claim 7, wherein the reducing comprises:
depositing a first oxide on at least a top, a left side, and a right side of each fin of the plurality of fins;
depositing a first nitride on the first oxide on at least the top, the left side, and the right side of each fin of the plurality of fins;
depositing a second oxide on the first nitride on a lower portion of both the left side and the right side of each fin of the plurality of fins;
depositing a second nitride on a portion of the first nitride and a portion of the second oxide exposed on each fin of the plurality of fins; removing a portion of the second nitride extending laterally beyond the second oxide on both the left side and the right side of each fin of the plurality of fins;
removing the second oxide from each fin of the plurality of fins;
removing a portion of the first nitride exposed on the left side and the right side of each fin of the plurality of fins;
removing a portion of the first oxide exposed on the left side and the right side of each fin of the plurality of fins;
removing a portion of the fin exposed on the left side and the right side of each fin of the plurality of fins, to yield a plurality of fins wherein each fin comprises a lower portion disposed on the semiconductor substrate and having a first width less than the initial width; and
removing the second nitride, first nitride, and first oxide from an upper portion of each fin of the plurality of fins, to yield a semiconductor device comprising the semiconductor substrate and a plurality of fins wherein each fin comprises an upper portion disposed on the lower portion and having a second width, wherein the second width is greater than the first width.

9. The method of claim 7, wherein the first width is about 14 nm and the second width is from about 20 nm to about 40 nm.

10. The method of claim 7, further comprising forming a gate on each fin of the plurality of fins, wherein the gate physically contacts at least a top, a left side, a right side, a left underside, and a right underside of at least the upper portion.

11. The method of claim 10, wherein the semiconductor device has a drive current at least about 10% greater than a drive current of a comparable semiconductor device comprising a plurality of comparable fins, wherein each of the comparable fins has a lower portion having the first width and an upper portion having the first width, and the semiconductor device has a leakage current no more than about 20% greater than a leakage current of the comparable semiconductor device.

12. The method of claim 7, wherein the forming the plurality of fins on a semiconductor substrate comprising forming the plurality of fins with a pitch from about 22 nm to about 48 nm.

13. The method of claim 7, wherein the second width is substantially equal to the initial width.

14. A system, comprising:
a process controller, configured to provide an instruction set for manufacture of the semiconductor device to a manufacturing system;
the manufacturing system, configured to manufacture the semiconductor device according to the instruction set, wherein the instruction set comprises instructions to:
form a plurality of fins on a semiconductor substrate, wherein each fin of the plurality of fins has an initial width; and
reduce a width of a lower portion of each fin to a first width, to yield a plurality of fins wherein each fin comprises an upper portion having disposed on the lower portion and having a second width, wherein the second width is greater than the first width.

15. The system of claim 14, wherein the instructions to reduce the width comprise instructions to:
deposit a first oxide on at least a top, a left side, and a right side of each fin of the plurality of fins;
deposit a first nitride on the first oxide on at least the top, the left side, and the right side of each fin of the plurality of fins;
deposit a second oxide on the first nitride on a lower portion of both the left side and the right side of each fin of the plurality of fins;
deposit a second nitride on a portion of the first nitride and a portion of the second oxide exposed on each fin of the plurality of fins;
remove a portion of the second nitride extending laterally beyond the second oxide on both the left side and the right side of each fin of the plurality of fins;
remove the second oxide;
remove a portion of the first nitride exposed on the left side and the right side of each fin of the plurality of fins;
remove a portion of the first oxide exposed on the left side and the right side of each fin of the plurality of fins;
remove a portion of the fin exposed on the left side and the right side of each fin of the plurality of fins, to yield a plurality of fins wherein each fin comprises a lower portion disposed on the semiconductor substrate and having a first width less than the initial width; and
remove the second nitride, first nitride, and first oxide from an upper portion of each fin of the plurality of fins, to yield a semiconductor device comprising the semiconductor substrate and a plurality of fins wherein each fin comprises an upper portion disposed on the lower portion and having a second width, wherein the second width is greater than the first width.

16. The system of claim 14, wherein the first width is about 14 nm and the second width is from about 20 nm to about 40 nm.

17. The system of claim 14, wherein the instruction set further comprises instructions to form a gate on each fin of the plurality of fins, wherein the gate physically contacts at least a top, a left side, a right side, a left underside, and a right underside of at least the upper portion.

18. The system of claim 17, wherein the semiconductor device has a drive current at least about 10% greater than a drive current of a comparable semiconductor device comprising a plurality of comparable fins, wherein each of the comparable fins has a lower portion having the first width and an upper portion having the first width, and the semiconductor device has a leakage current no more than about 20% greater than a leakage current of the comparable semiconductor device.

19. The system of claim 14, wherein the instructions to form the plurality of fins on a semiconductor substrate comprise instructions to form the plurality of fins with a pitch from about 22 nm to about 48 nm.

20. The system of claim 14, wherein the second width is substantially equal to the initial width.
